(19) United States
(12) Patent Application Publication
(10) Pub. No.: US 2007/0170996 A1
(43) Pub. Date: Jul. 26, 2007

(54) Plasma generating devices having alternative ground geometry and methods for using the same

(76) Inventors: David T. Dutton, San Jose, CA (US); Robert C. Taber, Palo Alto, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/485,051

(22) Filed: Jul. 11, 2006

Related U.S. Application Data
(60) Provisional application No. 60/760,496, filed on Jan. 20, 2006.

(51) Int. Cl. H03B 5/00

(52) U.S. Cl. 331/126

(57) ABSTRACT

Aspects of the invention include plasma generating devices having alternative ground geometries and systems thereof, as well as methods of using the same in plasma generation. The plasma generating devices of the invention include a resonator with a discharge gap disposed on a substrate and a ground element. Embodiments of the ground element of the plasma generating devices of the invention include those that are internal, external, coplanar or a combination thereof. The subject plasma generating devices, systems and methods find use in a variety of different applications.

### CROSS REFERENCE To RELATED APPLICATIONS

Applicant claims the benefit under 35 U.S.C. § 119(e) of prior U.S. provisional application Ser. No. 60/760,496 filed Jan. 20, 2006, the disclosure of which is incorporated herein by reference.

### BACKGROUND

A plasma is an ionized gas, and is usually considered to be a distinct phase of matter. “Ionized” in this case means that at least one electron has been dissociated from a proportion of the atoms or molecules. The free electric charges make the plasma electrically conductive so that it couples strongly to electromagnetic fields. The term plasma is generally reserved for a system of charged particles large enough to behave as one. Even a partially ionized gas in which as little as 1% of the particles are ionized can have the characteristics of a plasma (i.e. respond to magnetic fields and be highly electrically conductive).

Microwave plasma sources recently have been described (A. M. Bilgic et al., (2000), “A New Low-Power Microwave Plasma Source Using Microstrip Technology For Atomic Emission Spectrometry” Plasma Sources Sci. Technol 9 1-4; A. M. Bilgic et al., (2000) “A Low-Power 2.45 GHz Microwave Induced Helium Plasma Source At Atmospheric Pressure Based On Microstrip Technology”, J. Anal. At. Spectrom., 15, 579-580). The plasma sources described in these articles produce an electric field across a gap between a microstrip line present on one side of a dielectric and a ground plane on the opposite side of the dielectric. In these devices, the gap is defined by the dielectric thickness of the device, which typically is in the range of 0.5-1 mm. The structure is not resonant and requires a relatively larger power input to initiate (i.e., strike) a plasma. In addition, the structure is susceptible to failure as ions are accelerated by a plasma sheath voltage that forms between the plasma and the microstrip line. As a result, the microstrip electrode must be protected with a dielectric such as sapphire or glass. Ion erosion inherent in the design limits the usable lifetime of the device and wastes power, as power is expended in the ion erosion process rather than in the intended plasma generation.

Hopwood et al., (U.S. Pat. No. 6,917,165; herein incorporated by reference for its description of microwave frequency plasma generating devices) describes the use of a microstrip resonator at microwave frequencies for producing “non-thermal” plasmas at a gap in the same plane as the resonator. The circumference of the ring is a ½ wavelength at the operating frequency, and the location of the gap relative to the incoming microwave feed is designed to optimize the resonator's input impedance and maximize return loss at resonance. Voltages at the resonator ends on either side of the gap are 180° out of phase. The electric field at the gap is further enhanced by √Q of the resonator, where Q is the quality factor of the resonator [Q=2π (energy stored/energy dissipated)], and the small gap dimension, such that high electric fields are available to discharge a gas across the gap.

There is continued interest in the development of new devices and systems that can be employed for producing plasmas.

### SUMMARY OF THE INVENTION

Aspects of the invention include plasma generating devices having alternative ground geometries and systems thereof, as well as methods of using the same in plasma generation. The plasma generating devices of the invention include a resonator with a discharge gap disposed on/in a substrate and a ground element. Embodiments of the ground element of the plasma generating devices of the invention include those that are internal, external, coplanar or a combination thereof. The subject plasma generating devices, systems and methods find use in a variety of different applications.

### BRIEF DESCRIPTION OF THE FIGURES

FIGS. 1A and 1C provide exemplary views of single ground element geometries (internal, external, and co-planar ground elements). FIGS. 1B and 1D provide exemplary views of combined ground element geometries (internal &external, internal & co-planar, and internal & external & co-planar).

FIGS. 2A to 2C each provide views of an embodiment of a single resonator plasma generating device of the invention (external view and cross section). FIG. 2D provides a view of an embodiment of a multiplex plasma generating device of the present invention (external view only).

### DETAILED DESCRIPTION

Aspects of the invention include plasma generating devices having alternative ground geometries and systems thereof, as well as methods of using the same in plasma generation. The plasma generating devices of the invention include a resonator with a discharge gap disposed on/in a substrate and a ground element. Embodiments of the ground element of the plasma generating devices of the invention include those that are internal, external, co-planar or a combination thereof. The subject plasma generating devices, systems and methods find use in a variety of different applications.

Before the present invention is described in greater detail, it is to be understood that this invention is not limited to particular embodiments described, as such may vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed. It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

Plasma Generating Devices

As summarized above, the invention provides plasma generating devices having alternative ground element geometries (described in greater detail below). In certain embodiments, the subject plasma generating devices have a reduced substrate surface area of the plane containing the discharge gap that produces the plasma, e.g., as compared to devices in which a resonator and a ground plane are present on opposing surfaces of a planar substrate (e.g., where in certain embodiments the reduced substrate surface area is reduced by about 5% or more, such as by about 10% or more, including by about 15% or more). In certain multiplex embodiments, the resonators are located on a much closer pitch than can be achieved using devices where the resonator and a ground plane are disposed on opposing surfaces of a planar substrate. As such, one can obtain higher densities of discharge gaps for a given substrate surface area as compared to devices in which a resonator and a ground plane are present on opposing surfaces of a planar substrate. In certain embodiments, the density of discharge gaps per area of substrate surface may be 2 gaps/cm² or greater, such as 3 gaps/cm² or greater, 5 gaps/cm² or greater, and including 10 gaps/cm or greater, dependant upon the frequency of operation. Embodiments of the invention have multiple resonators, e.g., in working relationship with the same or different ground element(s), where such structures are referred to herein as multiplex plasma generating devices.

Embodiments of the invention are capable of producing plasmas under static gas and non-static gas conditions. By static gas condition is meant that the plasma is produced in an environment in which gas is not moving. By non-static-gas atmospheric conditions is meant that the plasma is produced in an environment in which gas, such as air, is moving. In certain of these embodiments, the subject plasma generating devices are capable of producing plasma with lower power inputs than those inputs employed for devices that are configured to generate plasmas under static gas conditions. In certain embodiments, the devices of the invention can produce plasmas using applied power ranging from about 0.1 W to about 50.0 W, such as from about 0.1 W to about 20 W and including from about 0.5 W to about 8 W.

Embodiments of the invention are capable of producing plasmas in atmospheric or non-atmospheric conditions. By atmospheric conditions is meant that the plasma is produced at atmospheric pressure in air. By non-atmospheric conditions is meant that the plasma is produced at non-atmospheric pressure (e.g., in a plasma tube or vessel). Embodiments of the subject plasma generating devices exhibit a low plasma bias, such that they have a long life-time. By long life time is meant that the devices can be employed to continuously produce a plasma without substantial degradation of the device, e.g., as may be caused by ion bombardment at electrical contacts. In certain embodiments, the devices can be employed to generate a plasma without substantial degradation in function for a period of time up to 50 hours of continuous operation or longer, such as up to 100 hours or longer and including up to 1000 hours or longer. Degradation in function can be measured by any convenient method.

Embodiments of the plasma generating devices of the invention include the following elements: a substrate; one (or more) resonator track(s) (e.g., a resonant ring) with a discharge gap disposed on a surface of the substrate; at least one ground element configured internally, externally, or co-planar to the one or more resonator track(s); and a connector coupled to the resonator track(s), e.g., for connecting a power source that supplies power to the resonator track(s). In general, a ground element(s) are positioned equidistant from its associated resonator track. By equidistant is meant that the distance separating the resonator track and its ground element(s) is the same (or substantially the same) around the entirety of the resonator track. In certain embodiments, the distance between the resonator track and its ground element(s) ranges from about 100 μm to about 5 mm, such as from about 100 μm to about 2 mm and including from about 1 mm to about 2 mm.

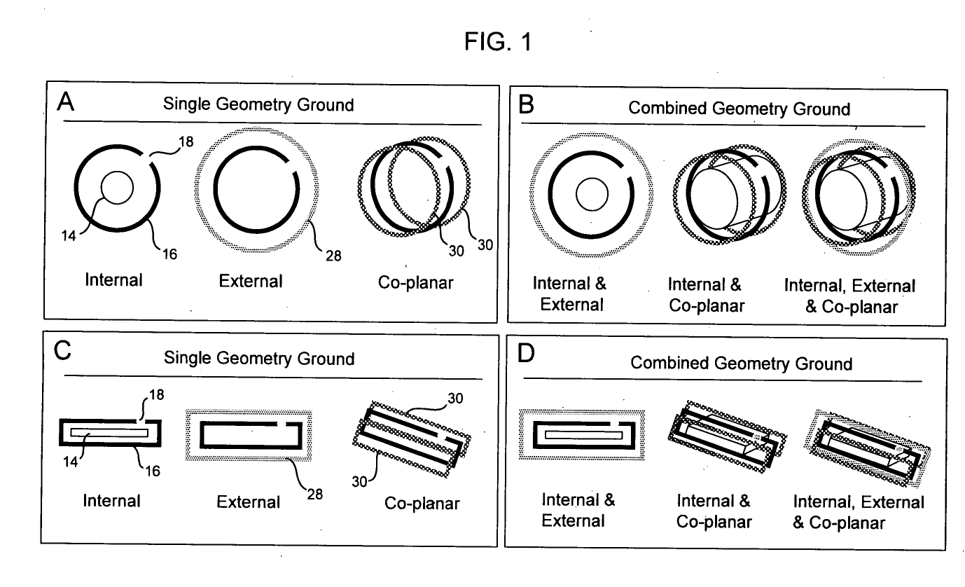

Embodiments of the subject plasma generating devices having single ground element geometries are shown in FIGS. 1A and C. In FIG. 1, only the cross sections of the ground and resonator track elements of plasma generating devices of the invention are shown (i.e., the substrate on which the resonator and ground elements are disposed is not shown). In FIG. 1A, a cross section of resonator track 16 is shown as a ring structure having either an internal ground element 14, an external ground element 28 or co-planar ground elements 30. FIG. 1C shows alternative embodiments in which cross sections of the resonator track and ground elements are not in a circular configuration. Like elements of FIGS. 1A and 1C are indicated with the same numbers.

By internal ground element is meant a ground element that is positioned on the interior of the resonator track (e.g., inside the resonant ring of FIG. 1A). In certain embodiments, the internal ground element is positioned within the substrate, i.e., is an internal feature of the substrate. The characteristic impedance, resonator impedance and quality factor (Q) of the resonator will be a function of two dimensions in this cross sectional plane (i.e., the distance between the resonator and the internal ground; and the resonator track height) and one dimension that is normal to this cross sectional plane (i.e., the resonator track width). In certain embodiments, the ground element is positioned within the substrate in a manner such that the ground element surfaces in at least one dimension ensure electrical connection to the ground, with all other dimensions covered with substrate material.

By external ground element is meant a ground element that is positioned exterior to the resonator track (e.g., outside the resonant ring of FIG. 1A). In certain embodiments the resonator is now embedded in the substrate and the ground is on the surface of the substrate or at an intermediate level of substrate material. Again, the characteristic impedance, resonator impedance and quality factor (Q) of the resonator will be a function of two dimensions in this cross sectional plane (i.e., the distance between the resonator and the external ground and the resonator track height) and one dimension that is normal to this cross sectional plane (i.e, the resonator track width).

By co-planar ground elements is meant ground elements that occupy planes positioned on opposing sides of the resonator track (e.g., in planes in front of and behind the resonant ring of FIG. 1A). In certain embodiments, the co-planar ground elements are of a similar geometry as the resonator track (e.g., as shown ion FIG. 1A). Whereas the area overlap between the internal and external ground with the resonator is determined by the resonator track width (normal to the cross section plane), the area overlap for the coplanar ground is determined by the resonator track height and is hence limited by metal thickness (e.g., 1-10 μm). This will result in lower Q values compared to the internal and external ground embodiments, where track widths, and hence area overlap, can be determined lithographically.

FIGS. 1B and 1D show exemplary embodiments of plasma generating devices in which more than one ground element is employed. Combining both internal and external grounds has the analogy of a stripline in conventional microwave circuit design. The addition of coplanar grounds in certain embodiments further enhances the Q of the resonator, and enables shielding between multiple resonators when built into arrays, preventing coupling between individual resonators. In certain embodiments, a plasma generating device of the invention contains all three ground elements (i.e., internal, external and co-planar). Certain of these embodiments can be analogized to a coaxial line in conventional microwave circuit design. In such embodiments, a rigid coaxial line can be used to manufacture single resonators in which the gap between the two ends of the rigid coaxial line is precisely located in space (e.g., using a mechanical jig) and the electrical feed to the resonator is carefully designed (e.g., to optimize plasma generation at the discharge gap).

FIGS. 1C and 1D show cross sections of geometries that are more favorable with manufacturing by multilayer technologies. For example, in certain embodiments horizontal surfaces of the resonator and ground planes are produced by screen printing or deposition and electroplating of metals, and vertical surfaces are produced via etch and metal fill technologies.

The plasma generating devices of certain embodiments include a power connector that is coupled to the resonator track, e.g., microstrip resonant ring, for connecting a power source that supplies power to the microstrip resonant ring during use. The connector can take a variety of configurations known in the art. For example, in certain embodiments, the connector is a subminiature type A (SMA) coaxial connector attached at right angles to the microstrip resonant ring and used to couple power to the device (similar to those described in Hopwood et al.; U.S. Pat. No. 6,917,165). Edge mounting SMA connectors can also be used.

In certain embodiments, the connector is linked to the resonator track by an additional transmission line. In general, the design of the resonator track geometry gives a primary impedance transformation, and no further transformation is required, hence the length of the additional transmission line does not affect the overall impedance of the device. However if the range of impedance transformation is not fully accommodated by the geometry of the resonator track, then the transmission line can be used as a further transformation by having a line width and hence characteristic impedance different to that of the resonator. Any convenient lengths and widths of this transmission can be employed.

In the plasma generating devices of the invention, the connector (or the transmission line) and the discharge gap are disposed in positions on the microstrip resonant ring to provide an impedance matched to that of a power source. By “matched” is meant that the impedance that is presented at the connector is equivalent to the output impedance of the power source such that maximum power transfer can be obtained. Any difference in these two impedance can result in a reflected component of power at the connector back towards the power source. In certain embodiments, the circumference of the microstrip resonant ring (or resonator track) is one-half wavelength (λ/2) at the operating frequency of the plasma generating device. When power is applied to the microstrip resonant ring, the maximum voltage difference occurs across the discharge gap. In certain embodiments, the magnitude of this maximum voltage difference ranges from about 50V to about 750V, such as from about 75V to about 600V and including from about 120V (0.5 W, 50 ohm, Q=110) to about 475V (8 W, 50 ohm Q=110). Thus, the electric field is concentrated in the discharge gap and, in certain embodiments, is at least double the magnitude of the electric field in the resonator track, which favors discharge breakdown in the discharge gap and minimization of losses in the resonator structure. The resonator dimensions and discharge gap length are determined in the design of specific embodiments to achieve the intended resonant frequency and performance characteristics, e.g., as exemplified below.

The discharge gap of the resonator can have a variety of dimensions and configurations so long as it is configured to provide for striking of plasma under conditions of use. In certain embodiments, the discharge gap is over the surface of the substrate whereas in other embodiments, the discharge gap extends into the substrate. The discharge gap of the resonator can vary in size, where the dimensions of the gap are selected to provide for plasma striking under intended parameters of use. In certain embodiments, the gap has a width (i.e., the distance between ends of the resonator) that ranges from about 20 μm to about 1 mm, such as from about 50 μm to about 500 μm and including from about 140 μm to about 200 μm. In certain embodiments, the gap width is from 20 μm to 200 μm.

In certain embodiments, the substrate 12 is a material that has a high dielectric constant (e.g., a dielectric material). By high dielectric constant is meant a dielectric constant that is 2 or higher, such as 5 or higher, including 9.6 (e.g., ceramic) or higher. Dielectric materials that find use as substrates in the invention include, but are not limited to, ceramic compounds, Teflon, polymers, glass, quartz and combinations thereof. In certain embodiments the substrate is fabricated from a single material whereas in certain other embodiments the substrate contains more than one material, e.g., different layers of distinct materials. The dimensions of the substrate can vary widely depending on the intended use of the plasma generated by the plasma generating device and/or the nature of the dimensions of the resonator employed, which are a function of the substrate dielectric properties, the frequency of operation and the characteristic impedance.

In certain embodiments, the ground element and the resonator are made of the same material, while in certain other embodiments they are made of different materials. The ground element and/or resonator can be fabricated from a variety of different materials including, but not limited to, Au, Cu, Ag and the like. The thickness of the resonator and the ground element can vary. In certain embodiments, the ground element has a thickness ranging from about 2 μm to about 10 μm, and including from about 6 μm to about 6.5 μm. In certain embodiments, the resonator has a thickness ranging from about 2 μm to about 10 μm, and including from about 6 μm to about 6.5 μm. In certain embodiments, the thicknesses of the resonator and the ground element are the same (or similar) whereas in other embodiments the thicknesses of these two components is different.

In certain embodiments, the resonator track is a microstrip resonator. In certain of these embodiments, the microstrip resonant ring can is disposed on the substrate by coating it with material for the microstrip layer (e.g., Au, Cu, etc.) followed by formation of the microstrip resonator structure by photo-lithographic and wet etching techniques which themselves are known in the art. Other processing techniques can be used to form the microstrip resonator structure. Depending on the -type and configuration of the ground element employed, similar methods may be used to form this structure.

In certain embodiments that employ a substrate-internal ground element, the substrate and the internal ground element have a similar shape such that the thickness of the substrate around the ground element is substantially the same (i.e., the distance from the outer surface of the substrate to the ground element/substrate interface is the same or substantially the same). The thickness of the substrate around the ground element (which is also the distance between the ground element and the resonator) can range from about 100 μm to about 5 mm, such as from about 100 μm to about 2 mm and including from about 1 mm to about 2 mm.

In certain embodiments, the substrate is a planar substrate. In certain of these embodiments, the substrate has a length ranging from about 5 mm to about 100 mm, such as from about 10 mm to about 70 mm and including from about 20 mm (actual ceramic) to about 50 mm (actual RT/DUROID®); a width ranging from about 5 mm to about 100 mm, such as from about 10 mm to about 70 mm and including from about 12 mm (actual ceramic) to about 40 mm (actual RT/DUROID®) and a thickness ranging from about 100 μm to about 5 mm, such as from about 100 μm to about 2 mm and including from about 1 mm (actual ceramic) to about 2 mm.

In certain embodiments, the substrate has a non-planar structure. For example, the substrate can have a cylindrical structure (e.g., a cylindrical substrate having cylindrical internal ground element and resonator, as shown in FIG. 1B). In these embodiments, the thickness of the substrate (i.e., the distance from the surface of the substrate to the substrate/internal ground element interface) is substantially the same.

In certain embodiments, the substrate and internal ground element have different structural characteristics (or geometries). For example, in certain embodiments, the substrate has a substantially planar configuration while the internal ground element is non-planar (e.g., cylindrical). The specific dimensions of the substrate and internal ground element will depend in part on the intended use of the device.

In certain embodiments, the plasma generating device of the invention produces static gas phase plasmas. Static gas phase plasmas are described in Iza, F., IEEE Trans on Plasma Science (2004) vol. 32(2) p. 498 and Hopwood, J., J Phys D (2005) vol. 38 p. 1698, the disclosure of which are herein incorporated by reference. In certain embodiments, the static-gas phase plasmas are produced under atmospheric conditions. In certain other embodiments, the static-gas phase plasmas are produced under non-atmospheric conditions (e.g., in a plasma tube or vessel). In certain of these embodiments, the plasmas are produced in a plasma tube having a specific gas (e.g., an inert gas) and having a specific pressure. Gasses of interest include, but are not limited to, inert gasses, e.g., argon, helium, xenon, nitrogen etc., as well as non-inert gasses/gas mixtures (e.g., atmospheric gasses). Pressures used in such plasma tube embodiments range from about 400 mTorr to about 760 Torr. The specific parameters for producing static-gas phase plasmas are dependent on the intended use of the plasma generating device.

In certain embodiments, the plasma generating device of the invention produces non-static gas phase plasmas. In these embodiments, the plasma generating device contains a gas flow element configured to flow gas through the discharge gap of the device. The flow of gas delivered by the gas flow element can be in a variety of directions relative to the discharge gap, where in certain embodiments the gas flow is such that gas flows from the bottom of the discharge gap to the top of the discharge gap, such that when a plasma is struck from the gas a plasma jet is produced on the top surface of the discharge gap. In certain embodiments, the gas flow element flows gas in a direction that is substantially orthogonal, and in certain embodiments orthogonal, to the discharge gap. By orthogonal is meant that the gas flow is at a right angle (90°) (or substantially normal) to a line connecting the center of the discharge gap leads. By “substantially orthogonal” is meant that the angle of the gas flow through the discharge gap is ±15°, such as ±10°, including ±5° of orthogonal.

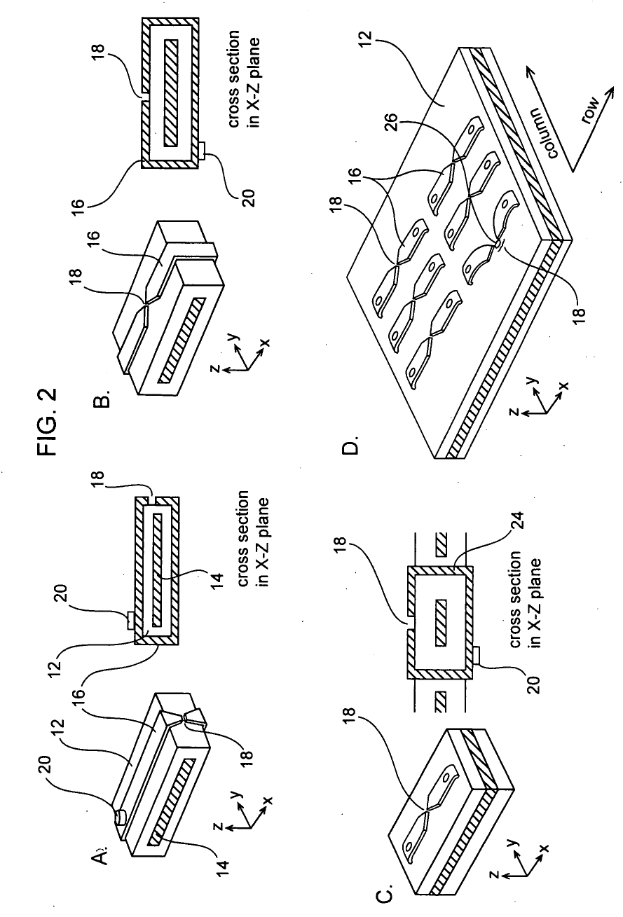

In other embodiments, the gas flow element can flow gas in a direction that is not orthogonal to the substrate. In certain of these embodiments, the gas flow delivered by the gas flow element is in substantially the same plane as the substrate surface on which the resonator is disposed (e.g., the Z/Y plane in FIG. 2A or the X/Y plane in FIG. 2B). In certain of these embodiments, the gas flow is substantially orthogonal to the discharge gap (as described above). As in the above embodiment, by “substantially orthogonal” is meant that the angle of the gas flow is ±15°, such as ±10°, including ±5° of orthogonal.

The gas flow element can be configured in a variety of ways. In certain embodiments, the gas flow element is integral to the substrate. For example, the gas flow element may be etched, molded, or drilled directly onto/into the substrate and/or ground element. In certain other embodiments, the gas flow element is a separate element that is capable of conveying a gas from a first location to second location, e.g., gas line, which is stably attached, e.g., affixed, to the structure in a manner sufficient to provide for the desired gas flow through the gap during use. The gas flow element may be fabricated from the same material as or a different material than the materials from which the other components of the device are fabricated, e.g., the substrate. In embodiments having gas flow elements, they are implemented in such a way as to not adversely affect the plasma generating function of the device. For example, if the dielectric constant of the material of the gas flow element affects the field lines above the resonator, the optimum matched conditions of the resonator may need to be adjusted. Optimization of such resonator function is within the capabilities of those of skill in the art.

In certain embodiments, the plasma generating device contains a gas feed connector coupled to the gas flow element (not shown). The gas feed element is configured to attach a gas feed line to the gas flow element, and may include a number of different components, e.g., nozzles, lips, threads, gaskets, etc., made from a variety of different materials, e.g., rubber, silicone, etc. The gas feed connector can be disposed in any convenient location on the plasma generating device. In certain other embodiments, the gas feed connector may be detached from the device. The configuration of the connector will depend, at least in part, on the nature of the gas flow element being employed.

As indicated above, in certain embodiments, flowing gas through the discharge gap allows striking plasmas using lower power inputs than those inputs employed for devices that are configured to generate plasmas under static gas conditions. In certain embodiments, the devices of the invention can produce atmospheric plasmas using applied power ranging from about 0.1 W to about 50.0 W, such as from about 0.1 W to about 20 W, such as from about 0.1 W to about 10 W and including from about 0.5 W to about 8 W.

The plasma generating devices of the invention generate plasmas at the electric field across the discharge gap as opposed to from field lines between the microstrip resonant ring and the ground plane, which feature distinguishes the subject devices and plasmas generated using other plasma generating devices, e.g., micro hollow cathode, cathode boundary layer and Dielectric Barrier Discharge (DBD) plasma generating devices, in which two contacts are required to sustain the field. The resonator of the plasma generating device of the present invention is essentially a one surface contact.

In certain embodiments, the plasma generating devices include two or more distinct resonators in operative relationship with the same or different ground elements, where devices of such embodiments are referred to herein as multiplex plasma generating devices. Such multiplex plasma generating devices are capable of producing more than one plasma. In certain embodiments, two or more resonators are configured to produce plasmas when connected to the same power source, e.g., where the two or more distinct resonators are operatively associated with different portions of the same ground element. As such, the connector and the discharge gaps of the two or more resonators are disposed in positions to provide an impedance matched to that of a common power source.

In certain other embodiments, the two or more resonators of the plasma generating device are in operative relationship with different ground elements. In such embodiments, the devices may be connected to individual power sources during use. In embodiments with more than one power source, the power sources may supply microwave power at the same, substantially the same, or different frequencies.

As noted above, the plasma generating devices of the invention enable the plasmas of a multiplex plasma generating device to be located on a much closer pitch than can be achieved in other configurations, e.g., as described above. In general, the definition of the ground element geometry (as described above) allows multiple resonators to be processed in close proximity of each other using multi-level fabrication.

The multiplex plasma generating devices of the invention can contain any number of resonators, and as such no limit in this regard is intended. In certain embodiments, the number of different resonators is 2 or more, such as about 10 or more, including about 100 or more and may be a great as about 1000 or more resonators. Further, the plasma generating devices in the multiplex plasma generating devices can be in virtually any configuration. In certain embodiments, the plasma generating devices are configured such that the discharge gaps (and thus the plasmas generated therefrom) occupy substantially the same plane and/or line (see e.g., FIG. 2D, discussed below). In certain of these embodiments, the discharge gaps are aligned in at least one column and/or row. In other of these embodiments, the discharge gaps are arranged in regular or irregular configurations including, but not limited to, circles, waves, angles, arcs, etc. In other embodiments, the discharge gaps of the multiplex device are not co-planar. For example, the discharge gaps may be disposed on the surface, either internal or external, of a regular or irregular three dimensional structure, e.g., a sphere, cylinder, cone, cube, bowl, pyramid, etc.

In certain embodiments, the substrate of the multiplex plasma generating devices is continuous. In certain of these embodiments, the internal ground element is also continuous. For example, in embodiments in which the discharge gaps are aligned in a single column, the ground element can be a single continuous element around which each of the multiple microstrip resonant rings are disposed (e.g., as shown in FIG. 1D, discussed below). In certain other embodiments, the internal ground elements of each of the single unit resonators are discontinuous, i.e., not in contact with each other. In these embodiments, the ground elements can be separated by the substrate, other material (e.g., a dielectric material), etc., or air.

In certain embodiments, the substrates have a discontinuous configuration. In these embodiments, each distinct resonator of the multiplex plasma generating device may contain the same or different substrates. In certain of these embodiments, the ground element is continuous whereas in other embodiments the ground element is discontinuous.

FIG. 2 shows exemplary embodiments of plasma generating devices having an internal ground element for use in multiplex applications. As indicated above, other ground element configurations find use in such multiplex applications (e.g., co-planar ground elements, combined internal & co-planar ground elements, etc.). In FIGS. 2A and 2B, plasma generating devices contain a substrate 12 with an internal ground element 14. A resonator track 16 having discharge gap 18 is disposed on the surface of the substrate 12 around the internal ground element 14. As indicated above, resonator tracks can have a variety of geometries and are not intended to be limited to those shown in the FIGS. 1 and 2. As such, the terms “resonator”, “resonant ring”, “resonator track”, etc., refer to any circular or non-circular shaped resonator, which can include for example circular, elliptical or oval and other non-circular rings, and rectangular or other multisided shapes. The internal ground element 14 is not continuous to ensure that the microstrip resonant ring section that runs down the vertical side of the substrate has sufficient separation from the ground element (i.e., the resonator track and the internal ground element are equidistant).

FIG. 2A shows the discharge gap 18 on the side surface of the plasma generating device (i.e., in the Z-Y plane), and FIG. 2B shows the discharge gap on the top surface of the plasma generating device (i.e., in the Y-X plane). While the cross-sections of both plasma generating devices shown in FIGS. 2A and 2B are rectangular, other cross sectional configurations are possible. For example, the plasma generating devices shown in FIGS. 2A and 2B could have rounded corners. In addition, in certain embodiments, substantially cylindrical substrate and internal ground elements may be employed (e.g., similar to those shown in FIGS. 1A and 1B).

The configurations shown in FIGS. 2A and B allow close stacking (i.e., multiplexing) of plasma generating devices in the Y direction. In certain multiplexing embodiments, additional co-planar ground elements are employed. In these embodiments, the co-planar ground elements are positioned between each of the multiplexed resonator tracks, thereby shielding the resonator tracks from each other. In other words, the co-planar ground elements isolate each resonator and its discharge gap from the next. By reducing potential interference between resonator tracks, these additional ground elements allow closer packing of the discharge gaps in these multiplex embodiments.

While the plasma generating devices shown in FIG. 2 have cross-sections that are rectangular, other cross sectional configurations are possible. For example, the plasma generating devices shown in FIG. 2 could have rounded corners. Other configurations are also possible (as discussed above).

In the embodiments shown in FIGS. 2A and 2B, the dimension of the substrate in the X direction is limited by the size of the microstrip resonant ring. However, the substrate dimensions need not be limited in such a way. For example, FIG. 2C shows a representative embodiment of a plasma generating device of the invention in which the sides of the microstrip resonant ring 16 pass through vias (i.e., throughways) 24 in the substrate. In this configuration, multiple resonators (i.e., with discharge gaps 18 on the upper surface) may be positioned in both X and Y directions (e.g., as depicted in the multiplex plasma generating device shown in FIG. 2D, discussed below).

In certain embodiments, the plasma generating device may comprise a via 26 (e.g., as shown in FIG. 2D, discussed below) through which a gas and/or liquid can be delivered to the discharge gap. This via can be disposed in the substrate and/or ground element in a variety of directions providing that it does not interfere with the ability of the plasma generating device's ability to strike a plasma under operating conditions.

FIG. 2D shows one embodiment of a multiplex plasma generating device of the invention in which the discharge gaps of the resonators are arranged in columns and rows (indicated with the arrows) on the same surface of a continuous planar substrate having internal ground elements. This multiplex device comprises six distinct resonators. In this embodiment, substrate 12 is a continuous structure with multiple discontinuous internal ground elements (not shown) each encircled by a resonator 16. In this embodiment, one of the surface microstrip resonant rings curves away from the central line of the ring thereby forming a discharge gap 18 that is not in the plane of the rest of the microstrip resonant rings. This configuration enables via 26 to be located at the microstrip discharge gap 18 and to penetrate all the way through the substrate without interfering with the microstrip on the reverse side of the substrate and/or the internal ground element.

By varying parameters such as discharge gap alignment, resonator ring curvature, ground element type and position, and via location, various gas/fluid flow configurations can be realized (as described in copending U.S. patent application Ser. No. ______ and its priority U.S. provisional application Ser. No. 60/760,560 (Attorney docket nos. 10060104-2 and 10060104-1); and copending U.S. patent application Ser. No. ______ and its priority U.S. provisional application Ser. No. 60/760,872 (Attorney docket nos. 10060106-2 and 10060106-1; the disclosures of which are herein incorporated by reference for there descriptions of microwave resonator plasma generating devices). For example, via 26 can be used as a gas flow element and/or an analyte feed as described in the section below. In certain multiplex plasma generating devices containing a gas flow elements, the gas flow elements may be configured to flow gas through one discharge gap or more than one discharge gap.

The above description of plasma generating devices (both individual and multiplex) according to various embodiments of the invention is provided for illustrative purposes only and is not meant to be limiting.

Systems

Also provided by the subject invention are systems that include the plasma generators, e.g., as described above. Aspects of these system embodiments of the invention include systems having a power source and a plasma generating device as described above.

In certain embodiments, the resonator of the plasma generating device is coupled to a power source that supplies power to the resonator in a manner sufficient to generate plasma at the discharge gap of the resonator. The power supply is connected to the resonator using any convenient coupling element, e.g., such as the connectors described above. In certain embodiments, the power supply is of such a small size and compact construction such that it is integrated into associated equipment, e.g., so that it is easily transportable for field use or for other portable applications. In certain embodiments, the power source is an integrated circuit power amplifier. In certain of these embodiments, the system contains a feedback path between the resonator and an input of the power source to provide oscillation and frequency control of the power source, e.g., at a power amplifier component of the power source.

In certain embodiments, the systems of the invention further contain a bias element (e.g., a bias coil). In these embodiments, the bias element may be positioned such that it has one end coupled to the resonator of the plasma generating device and the other end having a connector for application of a bias voltage. In these embodiments, the bias element has a microstripline length that is ¼ wavelength such that the DC power supply that is applying the additional voltage will be isolated from the RF power. The additional voltage provided by the bias element allows the plasma to be at a positive or negative voltage with respect to ground, and as such finds use in a number of embodiments. For example, ions produced from the plasma could be accelerated to a surface, or could be accelerated into another local microplasma for further ionization.

In certain embodiments, the system contains a gas feed coupled to a gas flow element configured to flow gas through the discharge gap of the plasma generating device (described above). The gas feed is configured to deliver a stream of gas, e.g., an inert or non-inert gas or gas mixture (as reviewed in greater detail below), to the gas flow element and through the discharge gap.

In certain embodiments, the plasma producing system of the invention further includes a detector configured to detect ionized species in the plasma produced by the system, where detectors of interest include, but are not limited to: optical spectrometers, mass spectrometers, ion mobility spectrometers, etc. In certain of these embodiments, the system further contains a readout for the detector. In certain embodiments, the plasma producing system of the invention contains an analyte feed for delivering an analyte or other sample to the plasma. The plasma producing systems of the invention can have a variety of configurations which will depend on the intended use of the system.

Methods

Aspects of the invention also include methods of producing plasmas using the devices and systems of the invention, e.g., as described above. In using the subject devices and systems to produce a plasma, an electric discharge at the discharge gap of a plasma generating device of the invention is produced sufficient to strike a plasma at the discharge gap. In certain embodiments, an electric discharge at the discharge gap of an additional plasma generating device of the invention is produced that is sufficient to strike a plasma at its discharge gap.

In certain embodiments, a gas is flowed from a gas feed through at least one discharge gap when producing a plasma at the discharge gap. In certain embodiments, the gas flow is directed though multiple discharge gaps. In these embodiments, a variety of different gases may be flowed through the discharge gaps. Gasses of interest include, but are not limited to, inert gasses, e.g., argon, helium, xenon, nitrogen, etc., as well as non-inert gasses/gas mixtures (e.g., atmospheric gasses). The flow rate of gas through the discharge gap may also vary. In certain embodiments, the flow rate of gas through the discharge gap ranges from about 1 standard cubic centimeters per minute (sccm) to about 1000 sccm, such as from about 5 sccm to about 500 sccm and including from about 10 sccm to about 100 sccm.

In certain embodiments, an analyte or sample is delivered to and ionized by the plasma. In these embodiments, the ionized sample/analyte may be detected using the detection systems (described below).

The power applied to the resonator(s) may vary depending on the particular configuration of the device, the environment and the desired properties of the plasma to be produced, so long as the applied power is sufficient to produce a discharge at the discharge gap that is sufficient to produce a plasma. In certain embodiments, the power level employed to strike an atmospheric plasma using the systems of the invention ranges from 0.1 W to 50.0 W, such as from about 0.1 W to about 10 W and including from about 0.5 W to about 8 W. In certain embodiments, the resonator has a Q of about 110 and return loss of about 30 dB.

Utility

The close packing of oriented resonators of multiplex embodiments of the invention provides plasma generating devices that find use in a variety of different applications. Applications of interest include, but are not limited to, gas sensors, e.g., in which the optical emission from atoms and molecules is sensed by a spectrometer. From the wavelength and intensity of photon emission from the plasma, the quantity and type of gas constituents may be determined. The present invention may also be used as an ionizer in which the atoms and molecules in a gas stream are ionized and then identified by a mass spectrometer or ion mobility spectrometer. The plasma produced by the subject devices/systems/methods may also be used as a source of chemically reactive gas. For example, the plasma excitation of air produces molecular radicals that can be employed to render non-infectious many biological organisms such as bacteria. The radicals from the plasma may also be used to remediate toxic chemical substances such as chemical weapons and industrial waste products. In addition to plasma cleaning applications, the plasma may be part of a miniature chemical production system in which gas flows of reactant species are directed through the plasma where the chemicals react in a controlled manner to produce a useful chemical product. This type of miniature chemical process system allows for portable, point-of-use production of volatile, short-lived, or dangerous chemicals. In yet other embodiments, the plasmas are useful as a source of light in the visible, ultraviolet, and the vacuum ultraviolet parts of the spectrum. In all of these applications, a number of plasma generating devices of the invention may be combined to cover a linear region or an extended area.

A non-limiting list of applications for the plasma producing system of the invention includes: a) material processing applications at atmospheric pressures using reactive gases, e.g., etching applications, such as etching of Si, KAPTON®, Polyimides, etc.; deposition applications, e.g., deposition of SiO₂, diamond, etc.; local surface modification applications, e.g., application in which a surface is changed from hydrophobic to hydrophilic; b) local heat treatment of surfaces; c) gas analysis applications, e.g., where a plasma is used to analyze surrounding air, or other environments, for example when coupled with optical emission spectroscopy; or where an analyte is added to carrier gas when coupled with optical emission spectroscopy, e.g., as described in provisional application Ser. No. 60/760,560, the disclosure of which is incorporated herein by reference; d) surface cleaning verification applications, e.g., as described in copending application Ser. No. 60/760,570 and application Ser. No. 11/397,064 having attorney docket no. 10050869-1; the disclosures of which are herein incorporated by reference; e) non-contact electrical probing applications, e.g., as described in copending application Ser. No. 11/020,337 (attorney docket no. 10041087-1) the disclosure of which is herein incorporated by reference; f) in micro thruster applications, e.g., where the produced plasma is employed as a source of thrust, e.g., for moving an object from a first to a second location; g) in micro light source applications, where the produce plasma is employed as a source of illumination; h) in large area light sources for lighting and photolithography; and i) cascaded ionization of one single gas channel by multiple resonators for optical emission spectroscopy or mass spectroscopy.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of the present invention is embodied by the appended claims.

What is claimed is:

1. A plasma generating device comprising:
i) a substrate;
ii) a resonator on a surface of said substrate, wherein said resonator comprises a discharge gap;
iii) at least one ground element having a geometry selected from the group consisting of: internal, external, and co-planar; and
iv) a power connector coupled to said resonator, wherein said power connector is configured for connecting a power source to said resonator.

2. The plasma generating device of claim 1, wherein said substrate has a high dielectric constant.

3. The plasma generating device of claim 1, wherein said connector and said discharge gap are disposed in positions on said resonator to provide an impedance matched to a power source.

4. The plasma generating device of claim 1, wherein said discharge gap has a width ranging from 20 μm to 200 μm.

5. The plasma generating device of claim 1, further comprising a transmission line that couples said power connector to said resonator.

6. The plasma generating device of claim 1, further comprising a gas flow element configured to flow gas through said discharge gap.

7. The plasma generating device of claim 1, wherein said device comprises two or more distinct resonators in operative relationship with said at least one ground element.

8. The plasma generating device of claim 1, wherein said device comprises at least two ground elements.

9. The plasma generating device of claim 8, wherein said device comprises two or more distinct resonators in operative relationship with said at least two ground elements.

10. The plasma generating device of claim 9, wherein said at least two ground elements comprise at least one co-planar ground element positioned between each of said two or more distinct resonators.

11. A system for producing a plasma comprising:
a) a power source; and
b) a plasma generating device comprising:
i) a substrate;
ii) a resonator on a surface of said substrate, wherein said resonator comprises a discharge gap;
iii) at least one ground element having a geometry selected from the group consisting of: internal, external, and co-planar; and
iv) a power connector coupled to said resonator, wherein said power connector is configured for connecting said power source to said resonator.

12. The system of claim 11, further comprising a gas feed coupled to a gas flow element configured to flow gas through said discharge gap.

13. The system of claim 11, further comprising an analyte feed.

14. The system of claim 11, further comprising a detector.

15. The system of claim 14, further comprising a readout for said detector.

16. The system of claim 10, wherein said plasma generating device comprises two or more distinct resonators in operative relationship with said at least one ground element.

17. The system of claim 16, further comprising at least one gas flow element configured to flow gas through at least one of said discharge gaps.

18. The system of claim 11, wherein said plasma generating device comprises at least two ground elements.

19. The system of claim 18, wherein said plasma generating device comprises two or more distinct resonators in operative relationship with said at least two ground elements.

20. The system of claim 19, wherein said at least two ground elements comprises at least one co-planar ground element positioned between each of said two or more distinct resonators.

21. The system of claim 20, further comprising at least one gas flow element configured to flow gas through at least one of said discharge gaps.

22. A method of producing a plasma comprising:
producing an electric discharge at the discharge gap of a plasma generating device according to claim 1 sufficient to strike a plasma at said discharge gap.

23. The method of claim 22, wherein said plasma generating device comprises two or more resonators and said method further comprises producing an electric discharge at the discharge gaps of at least two of said two or more resonators sufficient to strike a plasma at said discharge gaps.

24. The method of claim 22, further comprising flowing gas through said discharge gap.
